(19) United States
(12) Patent Application Publication
(10) Pub. No.: US 2023/0238298 A1
(43) Pub. Date: Jul. 27, 2023

(54) SEMICONDUCTOR DEVICE

(71) Applicant: Mitsubishi Electric Corporation, Tokyo (JP)

(72) Inventor: Masaaki ISHINO, Tokyo (JP)

(73) Assignee: Mitsubishi Electric Corporation, Tokyo (JP)

(21) Appl. No.: 18/057,583

(22) Filed: Nov. 21, 2022

(30) Foreign Application Priority Data
Jan. 27, 2022 (JP) 2022-010592

(51) Int. Cl. H01L 23/367

(52) U.S. Cl. CPC H01L 23/3677

(57) ABSTRACT

An object is to provide a technology to suppress temperature unevenness in a semiconductor device while suppressing deterioration in productivity. A semiconductor device includes a heat sink having heat radiating fins on one surface side thereof, a plurality of semiconductor modules arranged on an other surface side of the heat sink, and a plurality of heat radiation members provided between the plurality of semiconductor modules and the heat sink, respectively, in which of the plurality of heat radiation members a thickness of the heat radiation member provided between the semiconductor module susceptible to temperature rise and the heat sink is thinner than a thickness of the heat radiation members other than thereof.

### BACKGROUND OF THE INVENTION

### Field of the Invention

The present disclosure relates to a semiconductor device.

### Description of the Background Art

A semiconductor device including a plurality of semiconductor elements generates a loss due to the switching operation of the semiconductor elements and becomes high temperature. A heat sink is attached to the semiconductor device for cooling the semiconductor device which becomes high temperature.

For example, Japanese Patent Application Laid-Open No. 2020-188622 discloses a semiconductor device including a plurality of fins, a fin base having a first end face provided with the plurality of fins and a second end face opposite to the first end face, a first semiconductor module provided on the second end face, and a second semiconductor module provided on the second end face and provided in a first region being more on the windward side of the second end face than the first semiconductor module is.

In the technology described in Japanese Patent Application Laid-Open No. 2020-188622, a first thermally conductive member having a first thermal conductivity is provided between the second end surface and the first semiconductor module, a second thermally conductive member having a second thermal conductivity lower than the first thermal conductivity is provided between the second end surface and the second semiconductor module to suppress the rise in temperature unevenness among a plurality of semiconductor modules.

However, in the technique described in Japanese Patent Application Laid-Open No. 2020-188622, deterioration of productivity is concerned due to retooling or the like, which is required when assembling a semiconductor device because of the adoption of thermally conductive members made of different materials.

### SUMMARY

An object is to provide a technology to suppress temperature unevenness in a semiconductor device while suppressing deterioration in productivity.

The semiconductor device according to the present disclosure includes the heat sink, the plurality of semiconductor modules, and the plurality of heat radiation members. The heat sink has a heat radiating unit on one surface side thereof. The plurality of semiconductor modules are arranged on the other surface side of the heat sink. The plurality of heat radiation members are provided between the plurality of semiconductor modules and the heat sink, respectively. Of the plurality of heat radiation members, the thickness of the heat radiation member provided between the semiconductor module susceptible to temperature rise and the heat sink is thinner than the thickness of the heat radiation members other than that.

By suppressing the temperature rise of the semiconductor module susceptible to the temperature rise, suppression of the temperature unevenness in the semiconductor device is ensured. In addition, deterioration of productivity can be suppressed because providing heat radiation members made of different materials is not required. As described above, temperature unevenness in the semiconductor device can be suppressed while suppressing deterioration in productivity.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view of a semiconductor device according to a first embodiment;

FIG. 2 is a plan view of the semiconductor device according to the first embodiment;

FIG. 3 is a circuit diagram of the semiconductor device according to the first embodiment;

FIG. 4 is a cross-sectional view of a semiconductor device according to a first modification example of the first embodiment;

FIG. 5 is a plan view of the semiconductor device according to the first modification example of the first embodiment;

FIG. 6 is a plan view of the semiconductor device according to a second modification example of the first embodiment;

FIG. 7 is a plan view of a semiconductor device according to a third modification example of the first embodiment; and

FIG. 8 is a cross-sectional view illustrating a semiconductor module included in a semiconductor device according to a second embodiment.

### DESCRIPTION OF THE PREFERRED EMBODIMENTS

### First Embodiment

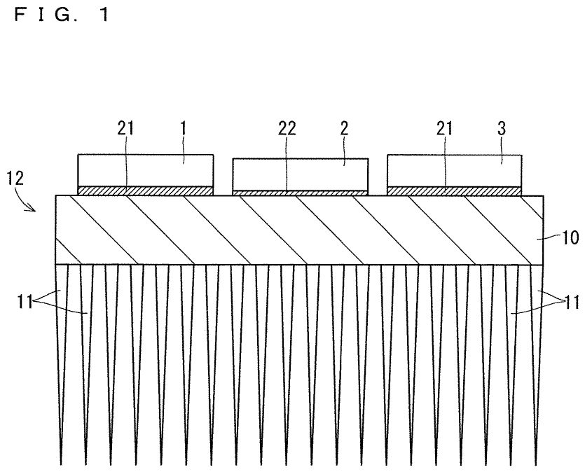

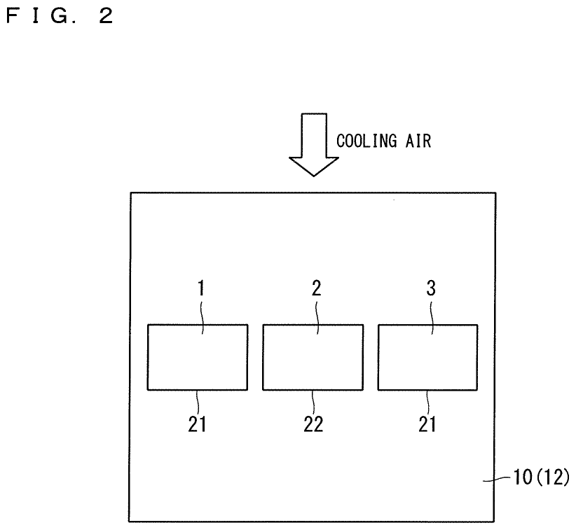

A first embodiment will be described below with reference to the drawings. FIG. 1 is a cross-sectional view of a semiconductor device according to the first embodiment. FIG. 2 is a plan view of the semiconductor device according to the first embodiment.

As illustrated in FIGS. 1 and 2, the semiconductor device includes a heat sink 12, a plurality of semiconductor modules 1, 2, 3, and a plurality of heat radiation members 21, 22, 21.

The heat sink 12 includes a fin base 10 and a plurality of heat radiating fins 11 as a heat radiation unit. The fin base 10 is formed in a plate shape, and the plurality of heat radiation fins 11 are provided on one surface side (lower surface side) of the fin base 10. The plurality of semiconductor modules 1, 2, 3 are arranged on the other surface side (upper surface side) of the fin base 10. A fan (not illustrated) is attached to the heat sink 12 to generate cooling air toward the plurality of radiator fins 11. In the first embodiment, a case where three semiconductor modules 1, 2, 3 are attached to the heat sink 12 will be described.

Between the three semiconductor modules 1, 2, 3 and the heat sink 12, each of the three heat radiation members 21, 22, 21 is provided, respectively. The three heat radiation members 21, 22, 21 are provided to improve the heat radiation property of the semiconductor device, and have the same thermal conductivity. That is, the same material is used for the heat radiation members 21, 22, 21.

The three semiconductor modules 1, 2, 3 are arranged in a straight line in a direction intersecting with the direction of the cooling air flowing through the heat sink 12. More specifically, the three semiconductor modules 1, 2, 3 are arranged in the straight line in the direction orthogonal to the direction of the cooling air.

Since the semiconductor module 2 is arranged in the center side of the semiconductor modules 1, 2, 3 arranged in a straight line, surrounded by the semiconductor modules 1, 3, and is susceptible to temperature rise. Therefore, the thickness of the heat radiation member 22 provided between the semiconductor module 2 susceptible to temperature rise and the heat sink 12 is formed thinner than the thickness of the heat radiation members 21 other than that.

Although the distinct difference in thickness between the heat radiation member 21 and the heat radiation member 22 is illustrated in FIG. 1, the actual difference in thickness therebetween is about several tens of μm and is hardly confirmed with the naked eye. The heat radiation member 21 provided between the semiconductor module 1 and the heat sink 12 and the heat radiation member 21 provided between the semiconductor module 3 and the heat sink 12 have the same thickness. Also, the three semiconductor modules 1, 2, 3 do not have to have the same external size, and the chip sizes of the semiconductor modules 1, 2, 3 do not have to be the same.

Here, the concept of the heat radiation members having the same thickness includes not only complete identicalness but also the case where slight differences due to a manufacturing error or the like are involved.

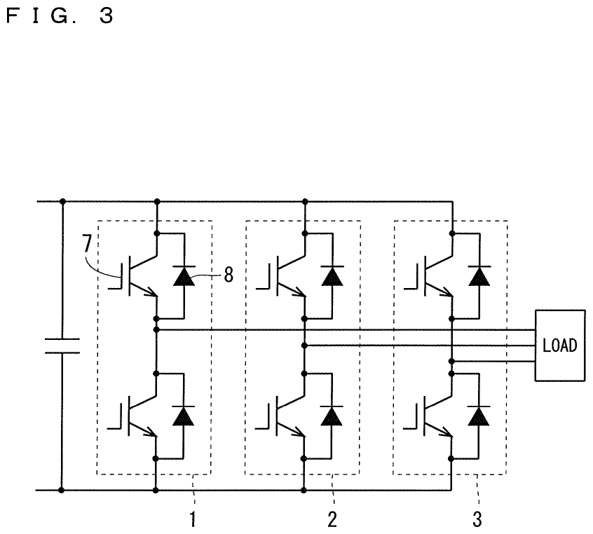

Next, the circuit configuration of the semiconductor device will be described. FIG. 3 is a circuit diagram of the semiconductor device according to the first embodiment. As illustrated in FIG. 3, three phases are configured where three phases are connected in parallel in which one phase is a series connection of sets of a switching element 7 and a diode 8 connected in antiparallel.

An IGBT, a MOSFET, or the like is adopted as the switching element 7. Although the description of the operation is omitted, heat is generated from the loss generated by the switching element 7 and the diode 8 caused by the switching operation of the switching element 7. The generated heat is transferred from the semiconductor modules 1, 2, 3 to the heat sink 12 through the respective heat radiation members 21, 22, 21, so that the temperature rise of the semiconductor modules 1, 2, 3 is suppressed.

At this point, temperature variations occur depending on the positional relationship of the semiconductor modules 1, 2, 3 due to interference of heat generated from the semiconductor modules 1, 2, 3. The semiconductor module 2 arranged in the center side of the semiconductor modules 1, 2, 3 is surrounded by the semiconductor modules 1, 3; therefore, it is susceptible to temperature rise. There is a problem that the life of the semiconductor module 2 becomes shorter than expected because the temperature of a specific semiconductor module 2 increases due to the occurrence of temperature variations.

The thermal resistance, an index, represents the rate of heat transfer from the semiconductor modules 1, 2, 3 to the heat sink 12, and is represented by the following expression using the thermal conductivity and length of the heat radiation members 21, 22, 21, and the cross-sectional area in contact with the heat sink 12. Here, the length of the heat radiation members 21, 22, 21 is synonymous with the thickness of the heat radiation members 21, 22, 21.

[Expression 1]

Thermal Resistance=Length/(Thermal Conductivity×Cross-Sectional Area) (1)

A temperature difference ΔT between the semiconductor modules 1, 2, 3 and the heat sink 12 is expressed by the following expression using the generated loss P and thermal resistance.

[Expression 2]

ΔT=P×Thermal Resistance=P×Length/(Thermal Conductivity×Cross-Sectional Area) (2)

When changing only the lengths of the heat radiation members 21, 22, 21, reducing the lengths (thicknesses) of the heat radiation materials 21, 22, 21 reduces the temperature difference ΔT between the semiconductor modules 1, 2, 3 and the heat sink 12 is reduced, thereby suppressing the temperature rise of the semiconductor modules 1, 2, 3.

In the first embodiment, the thickness of the heat radiation member 22 provided between the semiconductor module 2 and the heat sink 12 is made thinner than the thickness of the other heat radiation members 21, so that the heat conduction property from the semiconductor module 2 to the heat sink 12 is improved, thereby further suppressing the temperature rise in the semiconductor module

### <Effect>

As described above, the semiconductor device according to the first embodiment includes a heat sink 12 having the heat radiating fins 11 on one surface side, the plurality of semiconductor modules 1, 2, 3 arranged on the other surface side of the heat sink 12, and a plurality of heat radiation members 21, 22, 21 provided between the plurality of semiconductor modules 1, 2, 3 and the heat sink 12, respectively, in which, of the plurality of heat radiation members 21, 22, 21, the thickness of the heat radiation member provided between the semiconductor module susceptible to temperature rise and the heat sink 12 is thinner than the thickness of the heat radiation members other than that.

Therefore, by suppressing the temperature rise of the semiconductor module that is susceptible to the temperature rise, suppression of the temperature unevenness in the semiconductor device is ensured. In addition, deterioration of productivity be suppressed because providing heat radiation members made of different materials is not required. As described above, temperature unevenness in the semiconductor device can be suppressed while suppressing deterioration in productivity.

In addition, the plurality of semiconductor modules 1, 2, 3 are arranged in a straight line in a direction intersecting with the direction of the cooling air flowing through the heat sink 12, and the semiconductor module, that is susceptible to the temperature rise arranged in the center side of the straight line, is the semiconductor module 2.

Therefore, even if the temperature of semiconductor module 2 rises due to thermal interference thereto, suppression of the temperature variations among semiconductor modules 1, 2, 3 is ensured.

### <Modification Example of First Embodiment>

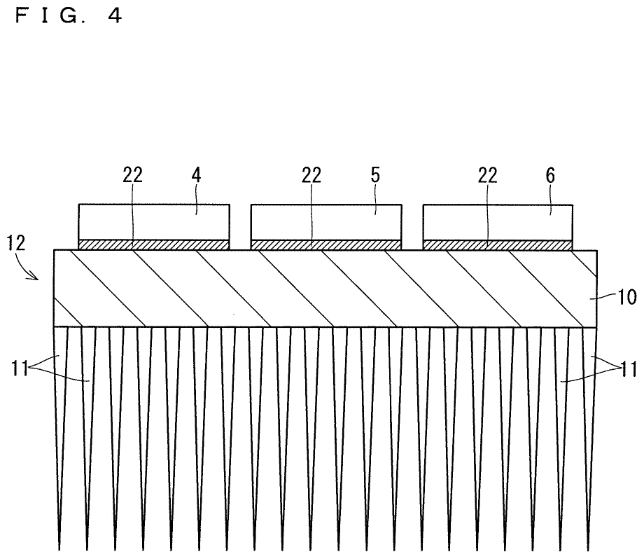

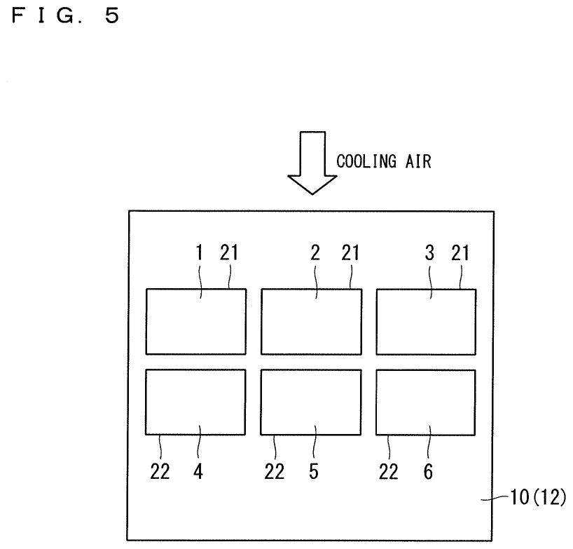

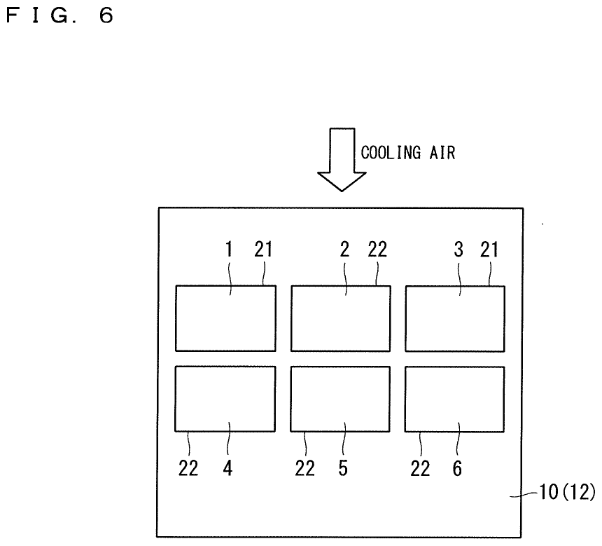

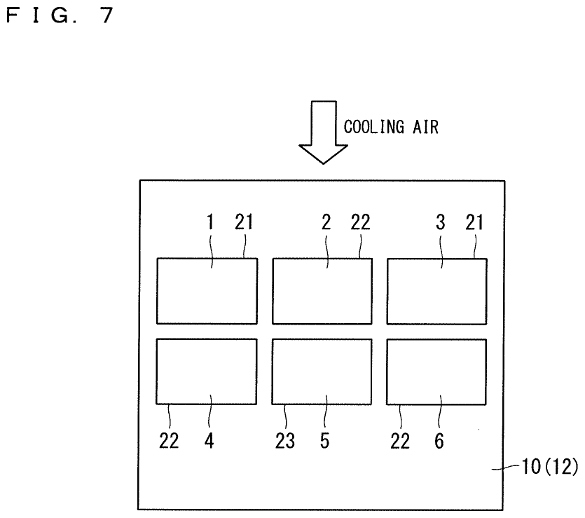

Next, a modification example of the first embodiment will be described. FIG. 4 is a cross-sectional view of a semiconductor device according to a first modification example of the first embodiment. FIG. 5 is a plan view of the semiconductor device according to the first modification example of the first embodiment. FIG. 6 is a plan view of a semiconductor device according to a second modification example of the first embodiment. FIG. 7 is a plan view of a semiconductor device according to a third modification example of the first embodiment.

As illustrated in FIGS. 4 to 7, the modification examples 1 to 3 of the first embodiment are examples in which six semiconductor modules 1, 2, 3, 4, 5, 6 are arranged. The six semiconductor modules 1, 2, 3, 4, 5, 6 are arranged in a straight line in a direction intersecting with the direction of the cooling air flowing through the heat sink 12 and are arranged in multiple rows along the direction of the cooling air. More specifically, the semiconductor modules 1, 2, 3 and the semiconductor modules 4, 5, 6 are arranged in a straight line in a direction orthogonal to the cooling air, and arranged in two rows along the direction of the cooling air. In other words, the semiconductor modules 4, 5, 6 are arranged in a row on the more leeward side of the cooling air than the semiconductor modules 1, 2, 3 are.

FIG. 5 illustrates a case where semiconductor modules susceptible to the temperature rise are assumed to be the semiconductor modules 4, 5, 6 arranged in a row on the leeward side of the cooling air. The thickness of the heat radiation materials 22, 22, 22 provided between the semiconductor modules 4, 5, 6 and the heat sink 12, respectively, is formed thinner than the thickness of the heat radiation materials 21, 21, 21 provided between the semiconductor modules 1, 2, 3, and the heat sink 12, respectively. The heat radiation members 21, 21, 21 have the same thickness, and the heat radiation members 22, 22, 22 have the same thickness as well.

On the leeward side of the cooling air, the semiconductor modules are less subject to cooling than on the windward side, and are susceptible to the temperature rise. The heat radiation materials 22, 22, 22 between the semiconductor modules 4, 5, 6 and the heat sink 12 on the leeward side are thinned to improve heat radiation property, thereby suppressing the temperature rise of the semiconductor modules 4, 5, 6 on the leeward side. Consequently, temperature variations between the semiconductor modules 1, 2, 3 on the windward side and the semiconductor modules 4, 5, 6 on the leeward side can be suppressed.

FIG. 6 illustrates a case where a semiconductor module susceptible to temperature rise is arranged in the center side of the straight line in the row on the windward side of the cooling air as the semiconductor module 2, and semiconductor modules susceptible to temperature rise are arranged in the row on the leeward side of the cooling air as the semiconductor modules 4, 5, 6, The thickness of the heat radiation materials 22, 22, 22, 22 provided between the semiconductor modules 2, 4, 5, 6 and the heat sink 12, respectively, is formed thinner than the thickness of the heat radiation materials 21, 21 provided between the semiconductor modules 1, 3 and the heat sink 12, respectively.

As described above, on the leeward side of the cooling air, the semiconductor modules are less subject to cooling than on the windward side, and are susceptible to the temperature rise. Since the semiconductor module 2 is arranged in the center side of the straight line on the windward side, surrounded by the semiconductor modules 1, 3, and is susceptible to temperature rise. The heat radiation materials 22, 22, 22, 22 between the semiconductor modules 2, 4, 5, 6 and the heat sink 12 are thinned, respectively, to improve heat radiation property, thereby suppressing the temperature rise of the semiconductor modules 2, 4, 5, 6. Consequently, temperature variations between the semiconductor modules 1, 3 and the semiconductor modules 2, 4, 5, 6 can be suppressed.

In addition to the case of FIG. 6, FIG. 7 illustrates a case where a semiconductor module susceptible to the temperature rise is assumed to be the semiconductor module 5 arranged in a center side in the straight line in the row on the leeward side of the cooling air. The thickness of the heat radiation materials 22, 22, 22, provided between the semiconductor modules 2, 4, 6 and the heat sink 12, respectively, is formed thinner than the thickness of the heat radiation materials 21, 21 provided between the semiconductor modules 1, 3 and the heat sink 12, respectively. Further, the thickness of the heat radiation material 23, provided between the semiconductor module 5 and the heat sink 12, respectively, is formed thinner than the thickness of the heat radiation materials 22, 22, 22 provided between the semiconductor modules 2, 4, 6, and the heat sink 12, respectively.

The semiconductor module 5, arranged in the center side of the straight line on the leeward side of the cooling air, is less subject to cooling than on the windward side and is susceptible to temperature rise because it is surrounded by the semiconductor modules 4, 6. The heat radiation material 23 between the semiconductor module 5 and the heat sink 12 is thinned to improve heat radiation property, thereby suppressing the temperature rise of the semiconductor module 5. Consequently, temperature variations between the semiconductor modules 1, 3 and the semiconductor modules 2, 4, 6 can be suppressed.

### Second Embodiment

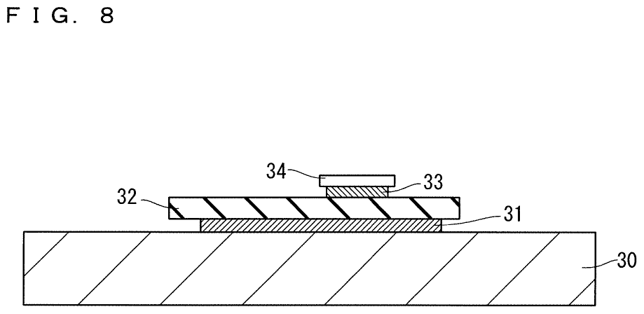

Next, a semiconductor device according to a second embodiment will be described. FIG. 8 is a cross-sectional view of a semiconductor module 1 included in the semiconductor device according to the second embodiment. It should he noted that, in the second embodiment, the same components as those described in the first embodiment are denoted by the same reference numerals, and the description thereof is omitted.

In the first embodiment, by thinning the thickness of a heat radiation member susceptible to the temperature rise provided between the semiconductor module and the heat sink 12, suppression of temperature unevenness in the semiconductor device is ensured while suppressing deterioration in productivity. In addition to this, the second embodiment aims at further suppression of temperature unevenness in the semiconductor device by changing the structure of the semiconductor module.

The semiconductor modules 1, 2, 3, 4, 5, 6 of the first embodiment and the first to third modification examples have the same structure; therefore, the description of the semiconductor module 1 will be made here. As illustrated in FIG. 8, the semiconductor module 1 includes a heat radiation plate 30, a semiconductor chip 34, and an insulating substrate 32.

The heat radiation plate 30 is made of metal and arranged on the heat sink 12 with the heat radiation member 21 interposed therebetween. The insulating substrate 32 is bonded to the upper surface of the heat radiation plate 30 via a bonding material 31 such as solder. The semiconductor chip 34 is arranged on the surface side opposite the surface provided on the heat sink 12 in the heat radiation plate 30. More specifically, the insulating substrate 34 is bonded to the upper surface of the insulating substrate 32 via a bonding material 33 such as solder.

Of the plurality of insulating substrates 32 provided in each of the plurality of semiconductor modules 1, 2, 3, 4, 5, 6, the thermal conductivity of the insulating substrates 32 provided in the semiconductor modules that are susceptible to temperature rise is higher than the thermal conductivity of the other insulating substrates 32 provided in the other semiconductor modules. The material of the insulating substrates 32 provided in the semiconductor modules that are susceptible to temperature rise is aluminum nitride (AlN), and the material of the insulating substrates 32 provided in the other semiconductor modules is aluminum oxide (Al₂O₃).

The heat generated in the semiconductor chip 34 is transferred to the heat radiation plate 30 through the insulating substrate 32 and propagates from the heat radiation plate 30 to the heat sink 12 through the heat radiation material 21. Employing the insulating substrate 32 with good thermal conductivity improves the heat radiation efficiency of the semiconductor device, and further suppression of the temperature variations in the semiconductor device is ensured.

In addition, the thickness of the insulating substrates 32 provided in the semiconductor modules susceptible to temperature rise is about 300 μm, and the thickness of the insulating substrates 32 provided in the other semiconductor modules is about 600 μm. In other words, in order to further improve the heat radiation efficiency of the semiconductor device, the thickness of the insulating substrates 32 provided in the semiconductor modules susceptible to temperature rise is formed thinner than the thickness of the insulating substrates 32 provided in the other semiconductor modules.

Further, in order to further improve the heat radiation efficiency of the semiconductor device, the thickness of the heat radiation plates 30 provided in the semiconductor modules susceptible to temperature rise is formed thicker by several mm than the thickness of the heat radiation plate 30 provided in the other semiconductor modules.

As described above, in the second embodiment, each of the semiconductor modules 1, 2, 3, 4, 5, 6 includes the heat radiation plate 30 arranged on the heat sink 12 via the heat radiation member, the semiconductor chip 34 arranged on the surface side opposite the surface provided on the heat sink 12 in the heat radiation plate 30, and the insulating substrate 32 provided between the semiconductor chip 34 and the heat radiation plate 30, in which, of the plurality of insulating substrates 32 provided M each of the plurality of semiconductor modules 1, 2, 3, 4, 5, 6, the thermal conductivity of the insulating substrates 32 provided in the semiconductor modules susceptible to temperature rise is higher than the thermal conductivity of the insulating substrates 32 provided in the other semiconductor modules.

Accordingly the heat radiation efficiency of the semiconductor device improves and further suppression of the temperature variations in the semiconductor device is ensured.

Further, of the plurality of heat radiation plates 30 provided in each of the plurality of semiconductor modules 1, 2, 3, 4, 5, 6, the thickness of the heat radiation plates 30 provided in the semiconductor modules susceptible to temperature rise is thicker than the thickness of the heat radiation plates 30 provided in the other semiconductor modules.

Accordingly the heat radiation efficiency of the semiconductor device improves further and further suppression of the temperature variations in the semiconductor device is ensured.

Further, of the plurality of insulating substrates 32 provided in each of the plurality of semiconductor modules 1, 2, 3, 4, 5, 6, the thickness of the insulating substrates 32 provided in the semiconductor modules that are susceptible to temperature rise is thinner than the thickness of the insulating substrates 32 provided in the other semiconductor modules.

Accordingly the heat radiation efficiency of the semiconductor device improves further and further suppression of the temperature variations in the semiconductor device is ensured.

### <Modification Example of First and Second Embodiments>

The number of semiconductor modules is not limited to three or six, and need only be two or more. Further, the number of semiconductor modules arranged in a straight line is not limited to three, and the number of semiconductor modules arranged along the direction of the cooling air is not limited to one row or two rows.

The embodiments can be arbitrarily combined, appropriately modified or omitted.

While the disclosure has been illustrated and described in detail, the foregoing description is in all aspects illustrative and not restrictive. It is therefore understood that numerous modifications and variations can be devised without departing from the scope of the invention.

What is claimed is:

1. A semiconductor device comprising:
a heat sink having a heat radiating unit on one surface side thereof;
a plurality of semiconductor modules arranged on an other surface side of the heat sink; and
a plurality of heat radiation members provided between the plurality of semiconductor modules and the heat sink, respectively, wherein
of the plurality of heat radiation members, a thickness of the heat radiation member provided between the semiconductor module susceptible to temperature rise and the heat sink is thinner than a thickness of the heat radiation members other than thereof.

2. The semiconductor device according to claim 1, wherein
each of the semiconductor modules includes a heat radiation plate arranged on the heat sink via the heat radiation member, a semiconductor chip arranged on a surface side opposite a surface provided on the heat sink in the heat radiation plate, and an insulating substrate provided between the semiconductor chip and the heat radiation plate, and
of the plurality of insulating substrates provided in each of the plurality of semiconductor modules, thermal conductivity of the insulating substrates provided in the semiconductor modules that are susceptible to temperature rise is higher than the thermal conductivity of the insulating substrates provided in other semiconductor modules.

3. The semiconductor device according to claim 2, wherein
of the plurality of heat radiation plates provided in each of the plurality of semiconductor modules, a thickness of the heat radiation plates provided in the semiconductor modules susceptible to temperature rise is thicker than a thickness of the heat radiation plates provided in the other semiconductor modules.

4. The semiconductor device according to claim 2, wherein
of the plurality of insulating substrates provided in each of the plurality of semiconductor modules, the thickness of the insulating substrates provided in the semiconductor modules that are susceptible to temperature rise is thinner than the thickness of the insulating substrates provided in the other semiconductor modules.

5. The semiconductor device according to claim 1, wherein
the plurality of semiconductor modules are arranged in a straight line in a direction intersecting with a direction of cooling air flowing through the heat sink, and
the semiconductor module susceptible to temperature rise is a semiconductor module arranged in a center in the straight line.

6. The semiconductor device according to claim 1, wherein
the plurality of semiconductor modules are arranged in a straight line in a direction intersecting with a direction of cooling air flowing through the heat sink, and are arranged in multiple rows along the direction of the cooling air, and
the semiconductor modules susceptible to temperature rise are semiconductor modules arranged in a row on a leeward side of the cooling air.

7. The semiconductor device according to claim 1, wherein
the plurality of semiconductor modules are arranged in a straight line in a direction intersecting with a direction of cooling air flowing through the heat sink, and are arranged in multiple rows along the direction of the cooling air, and
the semiconductor modules susceptible to temperature rise are the semiconductor module arranged in a center side in the straight line in a row on a windward side of the cooling air and semiconductor modules arranged in a row on a leeward side of the cooling air.

8. The semiconductor device according to claim 1, wherein
the plurality of semiconductor modules are arranged in a straight line in a direction intersecting with a direction of cooling air flowing through the heat sink, and are arranged in multiple rows along the direction of the cooling air, and
the semiconductor module susceptible to temperature rise is a semiconductor module arranged in a center side in the straight line in a row on a leeward side of the cooling air.
